(19) United States
(12) Patent Application Publication
(10) Pub. No.: US 2003/0227092 A1
(43) Pub. Date: Dec. 11, 2003

(54) Method of rounding a corner of a contact

(76) Inventors: De-Chuan Liu, Hsinchu (TW); Jung-Kuei Lu, Hsinchu (TW); Sheng-Shing Hwu, Miaoli City (TW)

Correspondence Address: Kenton R. Mullins, Stout, Uxa, Buyan & Mullins, LLP, Suite 300, 4 Venture, Irvine, CA, 92618, US

(21) Appl. No.: 10/163,042

(22) Filed: Jun. 5, 2002

(51) Int. Cl. H01L 23/48

(52) U.S. Cl. 257/774

(57) ABSTRACT

The present invention provides a method for forming a contact opening having a rounded corner. Because the corner of the formed contact opening is rounded, a conductive material that is free of voids can be formed within the contact opening. In the present invention, a dielectric layer and a patterned photoresist layer are sequentially formed on a substrate. An isotropic etching process and a main etching process are performed to form a contact opening in the dielectric layer. A photoresist descum process is performed to remove a portion of the photoresist layer. Then, a soft etching process is performed to form a rounded corner on the top of the contact opening. The contact opening can be substantially filled with a conductive layer.

### BACKGROUND OF THE INVENTION

1. Field of the Invention

The present invention relates generally to semiconductor fabrication methods and, more particularly, to methods for fabricating a contact opening having a rounded corner.

2. Description of Related Art

The fabrication of an integrated circuit involves numerous processing steps. After impurity regions are formed within a semiconductor substrate and gate areas defined upon the substrate, interconnect routing is placed across the substrate and connected to the impurity regions. An interlevel dielectric is formed between the interconnect routing and the substrate to isolate the two levels. Contact openings are formed through the dielectric and filled with a conductive material to electrically link the interconnect routing to select impurity regions in the substrate. Additional levels of interconnect routing separated by interlevel dielectric layers can be formed if desired. Different levels of the interconnect routing can be coupled together with ohmic contacts formed through the dielectric layers. Forming a multi-level integrated circuit in this manner reduces the overall lateral area occupied by the circuit.

In conventional methods, a contact opening (also called a via hole) is formed with a main etching process and a soft etching process. Since the formed contact opening has a right angle-like corner, a volcano defect can occur in the metal layer filled into the contact opening. FIGS. 1-3 demonstrate these methods and their limitations in more detail.

FIG. 1 depicts the formation of a patterned photoresist layer 19 on a dielectric layer 16 disposed upon a substrate 13. Photoresist layer 19 serves as an etching mask and is substantially resistant to attack by an etching agent (i.e., etchant) subsequently used to etch dielectric layer 16. As shown in FIG. 2, a main etching process followed by a soft etching process removes a portion of dielectric layer 16 not covered by photoresist layer 19, thereby forming a contact opening 22 in dielectric layer 16. Contact opening 22 expenses an impurity region residing in substrate 13.

In the main etching process, dielectric layer 16 is removed using, e.g., a dry, plasma etch that is anisotropic in nature, i.e., ion bombardment is greater in the vertical direction than in the horizontal direction. The plasma etch can be terminated before portions of substrate 13 are removed. A soft etching process can then be employed to improve the roughness of substrate 13. As a result of the anisotropic etch, the sidewalls of contact opening 22 are substantially perpendicular to the upper surface of dielectric layer 16. The corner at the top of contact opening 22 is therefore shaped like a right angle.

After removal of photoresist layer 19, a conductive material 23, such as tungsten or copper, is formed in contact opening 22. As shown in FIG. 3, conductive material 23 is typically formed within contact opening 22 using a physical vapor deposition process, e.g. sputtering, or a well-known electroplating technique. As conductive material 23 builds up along the walls of contact opening 22, the right angle corners at the top of the opening can cause the conductive material 23 to accumulate faster near the top. Consequently, conductive material 23 that forms on opposite sidewalls of contact opening 22 comes together at the middle of the top of contact opening 22 before the bottom of contact opening 22 is completely filled. In this manner, a void 25 is formed in conductive material 23. The continuous mass of conductive material 23 positioned at the top of contact opening 22 acts as a barrier that prevents more conductive material 23 from reaching void 25. As such, void 25 becomes a permanent defect in the ohmic contact placed in opening 22.

Therefore, using conventional methods to etch and fill contact opening 22 can undesirably lead to the formation of a volcanic defect (i.e., a void) in conductive material 23. Because air is not conductive, the presence of void 25 in conductive material 23 increases the resistance of the resulting ohmic contact and effectively reduces the conductivity of the contact. The conductivity of the contact may be low enough to render the integrated circuit inoperable.

A need thus exists in the prior art to eliminate the formation of a void in the conductive material used to fill an ohmic contact. A further need exists to develop a method for etching a contact opening in a way that would avoid the formation of a right angle-like corner at the top of the contact opening.

### SUMMARY OF THE INVENTION

The present invention addresses these needs by providing a method for forming a contact opening having a rounded corner. Because the corner of the formed contact opening is rounded, a conductive material can be formed within the contact opening with a reduced, and preferably no, occurrence of voids. As such, an ohmic contact is formed that is capable of reliably electrically coupling the underlying substrate to overlying interconnect routing subsequently formed above the dielectric level.

In accordance with one aspect of the invention, a dielectric layer and a patterned photoresist layer are sequentially formed on a substrate. A main etching process is performed to form a contact opening in the dielectric layer, and a photoresist descum process is performed to remove a portion of the photoresist layer adjacent to the contact opening. Then, a soft etching process is performed to form a rounded corner on the top of the contact opening. According to another aspect of the invention, an isotropic etching process can be performed before the main etching process, and the main etching process can be followed by an over etching process. The method can be used to form a plurality of contact openings having a rounded corners. Since the isotropic etching process is performed before the main etching process and the photoresist descum process is performed before the soft etching process, the corner of the formed contact opening can be rounded. Because the corner of the formed contact opening is rounded, a volcano defect can be avoided in the metal layer filled into the contact opening. The isotropic etching process, the main etching process, the photoresist descum process, and the soft etching process can be performed in-situ.

According to another aspect of the invention, a contact opening having a rounded corner at its top is formed using several process steps. First, a dielectric layer is deposited across a substrate. The dielectric layer may comprise a material capable of isolating the substrate from overlying conductive interconnects, e.g., borophosphosilicate glass (BPSG), silicon oxide, silicon nitride, or silicon oxy-nitride. A photoresist layer is then patterned on the substrate to form an etching mask for the subsequent removal of portions of the underlying dielectric layer. Next, an isotropic etching process (the rate of ion bombardment in the vertical direction is about equivalent to the rate of ion bombardment in the horizontal direction) and a main etching process are employed to form a contact opening in an exposed portion of the dielectric layer. The isotropic etching process is performed at a pressure of about 500-1000 mTorr and a power of about 100-300 W. The reactive gases of the isotropic etching process can be argon (Ar)/carbon tetrafluoride (CF₄)/trifluoromethane (CHF₃), wherein a flow rate of the Ar is about 50-150 sccm, a flow rate of CF₄ is about 10-30 sccm, and a flow rate of CHF₃ is 10-30 sccm. The main etching process employs, for example, a dry, plasma etch to remove portions of the dielectric layer.

As a result of the isotropic etching process and the main etching process, a contact opening is formed partially through the dielectric layer. The sidewall surfaces of the contact opening are non-perpendicular with respect to the upper surface of the dielectric layer such that the top of the contact opening is wider than the base of the contact opening. An over-etching process may be performed after the main etching process to finish removing the dielectric layer down to the substrate surface. A photoresist descum process is thereafter performed to remove a portion of the photoresist layer, thereby exposing the corners of the dielectric layer, which are located laterally adjacent to the top of the contact opening. The photoresist descum process is performed at a pressure of about 50-150 mTorr and a power of about 50-200 W. Oxygen gas (O₂) serves as the reactive gas of the photoresist descum process, wherein a flow rate of the reactive gas is about 5-80 sccm. The etch rate of the photoresist layer is about 2000-6000 angstroms (Å)/min, and the duration of the photoresist descum process can be about 10 to 60 seconds. After the photoresist descum process is completed, the exposed corners of the dielectric layer are subjected to a soft etching process, e.g., a dry, isotropic etch, for a period of time sufficient to substantially round those corners.

According to another aspect of the invention, a structure is formed that comprises a dielectric layer on a substrate and a contact opening extending vertically through the dielectric layer. A sidewall surface of the contact opening is substantially rounded at the top of the contact opening. The dielectric layer is preferably selected from the group comprising BPSG, silicon oxide, silicon nitride, and silicon oxy-nitride. A conductive material substantially fills the contact opening and thus forms an ohmic contact free of voids that would undesirably lower the conductivity of the otherwise highly conductive contact.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCIRPTION OF THE FIGURES

FIG. 1 is a cross-sectional view of a prior art silicon substrate upon which a dielectric layer has been formed, wherein a photoresist layer is patterned upon the dielectric layer in accordance with a conventional fabrication method;

FIG. 2 is a cross-sectional view of the prior-art configuration depicted in FIG. 1, wherein an exposed portion of the dielectric layer is etched to form a contact opening in the dielectric layer;

FIG. 3 is a cross-sectional view of the prior-art configuration depicted in FIG. 2, wherein a conventional method is employed to form a conductive material within the contact opening, resulting in the formation of a void in the conductive material;

FIG. 4 is a flowchart showing the formation of a contact opening in accordance with a preferred embodiment of the present invention;

FIG. 5 is a cross-sectional view of a silicon substrate upon which a dielectric layer is disposed, wherein a photoresist layer is patterned on the dielectric layer in accordance with a preferred embodiment of the present invention;

FIG. 6 is a cross-sectional view of the configuration depicted in FIG. 5, wherein an isotopic etch process and a main etching process are performed to partially form a contact opening in the dielectric layer in accordance with a preferred embodiment of the invention;

FIG. 7 is a cross-sectional view of the configuration depicted in FIG. 6, wherein an over-etching process is performed to complete the formation of the contact opening in accordance with a preferred embodiment of the invention;

FIG. 8 is a cross-sectional view of the configuration depicted in FIG. 7, wherein a photoresist descum process is performed to remove a portion of the photoresist layer in accordance with a preferred embodiment of the invention;

FIG. 9 is a cross-sectional view of the configuration depicted in FIG. 8, wherein a soft etching process is performed to form a rounded corner at the top of the contact opening in accordance with a preferred embodiment of the invention; and

FIG. 10 is a cross-sectional view of the configuration depicted in FIG. 9, wherein a conductive layer is formed within the contact opening in accordance with a preferred embodiment of the invention.

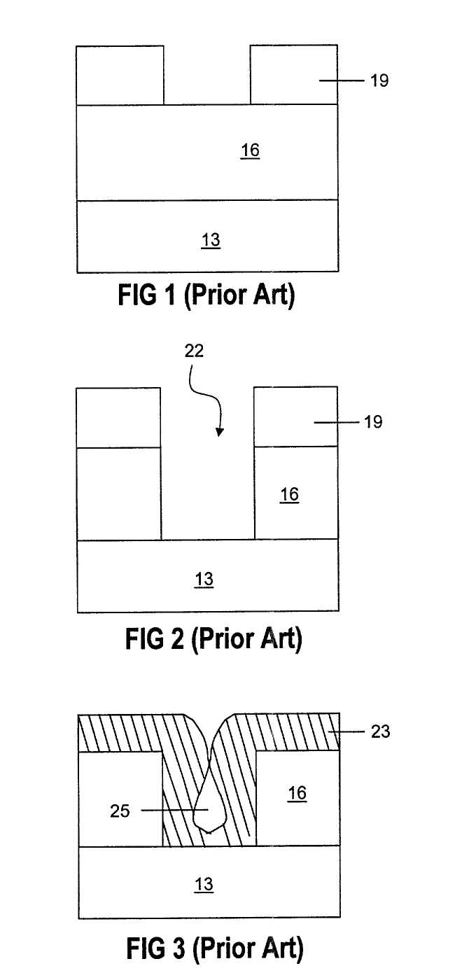

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. For example, it is understood by a person of ordinary skill practicing this invention that the fabrication method in accordance with the present invention includes forming a contact opening having a rounded corner at the top of the opening. Hence, the contact opening may be formed in different dielectric materials and at different levels of the integrated circuit than those described herein in exemplary embodiments. Moreover, the contact opening may be formed above different conductive materials located at different levels of the integrated circuit. For example, the contact opening may be formed down to a transistor gate rather than to a silicon substrate, as described herein. Thus, different dielectric materials and different conductive materials located at different levels can be implemented in accordance with the present invention.

It is to be understood and appreciated that the process steps and structures described herein do not cover a complete process flow for the manufacture of transistor devices. The present invention may be practiced in conjunction with various integrated circuit fabrication techniques that are conventionally used in the art, and only so much of the commonly practiced process steps are included herein as are necessary to provide an understanding of the present invention.

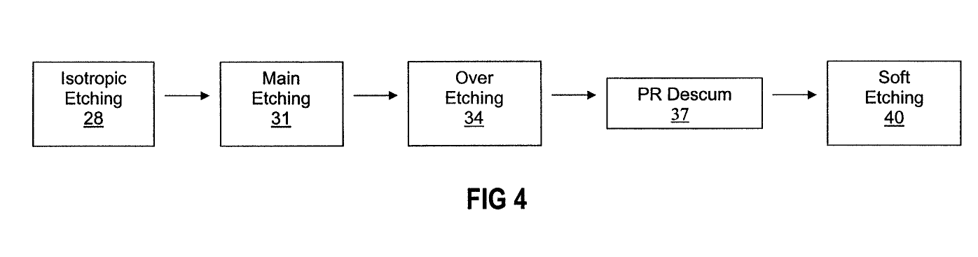

With reference to the drawings, FIG. 4 depicts a flowchart of a method for forming a contact opening having a substantially rounded corner at the top of the opening. The method can of course be used to form a plurality of contact openings, wherein each contact opening has a substantially rounded corner at the top of the opening. Fabrication of the contact opening commences at Step 28, wherein a dielectric layer on a substrate is subjected to isotropic etching. A patterned photoresist layer serves as a mask during the isotropic etching process such that a portion of the dielectric layer exposed by the photoresist layer is removed. At Step 31, the exposed portion of the dielectric layer is further subjected to a main etching process. In a modified embodiment, however, the isotropic etching process 28 may be omitted so that the method begins with the main etching process of Step 31. Then, at Step 34, an over-etching process is performed to remove the exposed portion of the dielectric layer down to the substrate surface to complete the contact opening. The photoresist later is then subjected to a photoresist descum process at Step 37 to remove the photoresist from above the corners of the dielectric layer near the top of the contact opening. The formation of the contact opening ends at Step 40, wherein a soft etching process is performed to round the corners at the top of the contact opening. The isotropic etching process, the main etching process, the photoresist descum process, and the soft etching process can be performed in-situ, wherein the wafer is maintained in a single reaction chamber during all of these processes. Accordingly, during the periods between these in-situ processes, the substrate remains free of contaminants that could otherwise damage or alter the structures on the substrate.

FIGS. 5-10 illustrate the formation of the contact opening having rounded corners by depicting cross-sectional views of the contact opening as it is being formed. Turning to FIG. 5, a substrate 43 is provided upon which a dielectric layer 46 is formed. Although substrate 43 preferably comprises single crystalline silicon, in alternative embodiments substrate 43 can comprise materials such as gallium nitride (GaN), gallium arsenide (GaAs), polysilicon, or other materials commonly recognized as suitable semiconductor materials to those skilled in the art. Substrate 43 may be slightly doped with p-type dopants (e.g., arsenic, phosphorus, and antimony) or n-type dopants (e.g., boron and boron difluoride), and it may include oppositely doped impurity regions (also called junctions). Dielectric layer 46 preferably comprises borophsphosilicate glass (BPSG), which may be formed using, e.g., a low-pressure chemical vapor deposition (LPCVD) process. The LPCVD of BPSG involves thermally decomposing tetraethyloxysilane (TEOS) gas in a reaction chamber maintained at a low pressure of about 0.1 to 1.0 Torr and a temperature of about 650 to 750° C. In addition to TEOS (Si(OC₂H₅)₄), a dilute mixture of phosphine (PH₃) and diborane (B₂H₆) is flowed into the reactor during the LPCVD process. The resulting BPSG layer is a silicon glass containing low concentrations of phosphorus and boron. Alternatively, dielectric layer 46 may comprise other insulating materials, such as silicon oxide, silicon nitride, or silicon oxy-nitride, all or which can be CVD deposited across substrate 43.

A patterned photoresist layer 49 exposing a portion of dielectric layer 46 is formed to act as an etch mask during the subsequent patterning of a contact opening. Photoresist layer 49 is patterned using a well-known lithography process. As is common in the art, a layer of photoresist is first spun onto a wafer comprising silicon substrate 43 and dielectric layer 46. The wafer is then placed into a patterning tool known as a “stepper” where it is aligned to a mask plate and exposed to ultraviolet (UV) radiation. The mask may only be large enough to cover a small portion of the wafer, in which case the stepper steps the wafer through many quadrants, each of them being exposed in turn until the entire or desired portion of the wafer has been exposed to UV light. The wafer is then placed in a developer solution that dissolves portions of the photoresist that were exposed to the UV radiation, thereby yielding patterned photoresist layer 49.

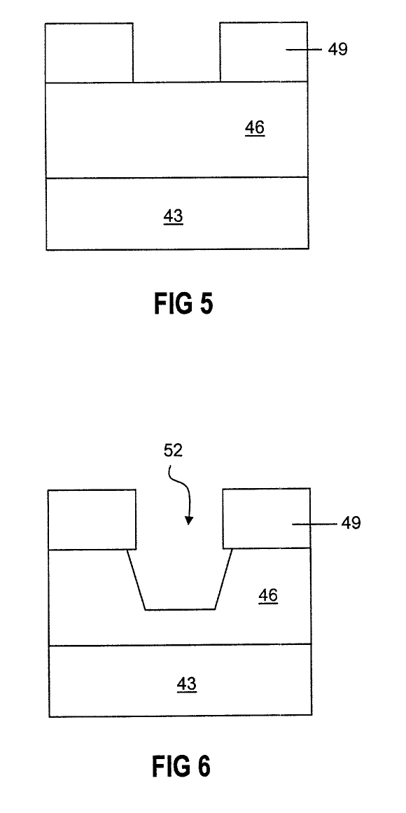

Turning to FIG. 6, an isotropic etching process and a main etching process are performed to form a contact opening 52 in a portion of dielectric layer 46 not covered by photoresist layer 49. The isotropic etching process removes portions of the dielectric layer 46 to thereby define sidewalls and a base of the opening 52. In the case where dielectric layer 46 comprises BPSG, the reactive gas for the isotropic etching process contains Ar/CF₄/CHF₃, wherein Ar is supplied to the reaction chamber at a flow rate of about 50 to 150 sccm, CF₄ is supplied at a flow rate of about 10 to 30 sccm, and CHF₃ is supplied at a flow rate of about 10 to 30 sccm. During the isotropic etching process, the reaction chamber is maintained at a pressure of about 500 to 1000 mTorr and a power of about 100 to 300 W. The etch rate of the BPSG using these process conditions is about 2578 Å/min, and the etching selectivity of the BPSG to the silicon substrate is about 86.5. As a result of the isotropic etching process, the sidewalls of contact opening 52 are formed to be non-perpendicular to a base of the contact opening 52, such that the top of the contact opening 52 is wider than the base. More particularly, the contact opening 52 at this stage will have somewhat rounded sidewalls with the top edge of the contact opening 52 extending slightly beneath the photoresist layer 49.

After the isotropic etching process, a main etching process, e.g., a relatively high-pressure plasma etch, is performed for a duration sufficient to anisotropically remove dielectric layer 46 to a level just above the substrate 43. In the illustrated embodiment, the wafer need not be removed from the reaction chamber between the isotropic etching process and the main etching process, for the same chamber and the same reactants can be used for both processes. For example, following the isotropic etching, the source power can be decreased and/or the bias power can be increased to render the etch more anisotropic for the main etching. As exemplified in FIG. 6, after the main etching the sidewalls of the contact opening 52 slope radially inwardly in a direction toward the base, such that the top of the contact opening 52 remains wider than the base of the contact opening 52.

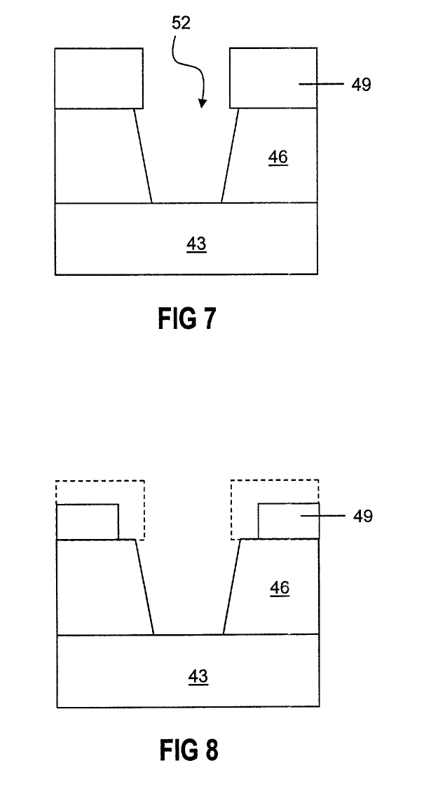

As shown in FIG. 7, an over-etching process may be performed subsequent to the main etching process to complete the formation of contact opening 52. The over-etching process employs a well-known etch technique, e.g., a dry, plasma etch, to remove the uncovered portion of dielectric layer 46 down to the surface of substrate 43. The etch duration can be selected to terminate before substantial portions of substrate 43 can be removed. Again, in the illustrated embodiment the same reaction chamber and the same reactants may be used for the over-etching process. As presently embodied, the optional over-etching process may be conducted at a slower and more controllable etch rate, compared to the main etch, by for example decreasing the sccm of the reactant gas to thereby ensure a greater selectivity of the dielectric layer 46 being etched with respect to the substrate 43.

Next, as shown in FIG. 8, a photoresist descum process is performed to remove a portion of photoresist layer 49 disposed laterally adjacent to the top of the contact opening 52. In the illustrated embodiment, a portion of the photoresist layer 49 is removed from above the corners of dielectric layer 46. The same reaction chamber as employed in the previous etching processes may be employed for the photoresist descum process. In the photoresist descum process, O₂, the reactive gas, is supplied to the reaction chamber at a flow rate of about 5 to 80 sccm. The pressure of the photoresist descum process is about 50 to 150 mTorr, and the power is about 50 to 200 W. Photoresist layer 49 etches at a rate of about 2000 to 6000 Å/min, and the photoresist descum process is terminated after about 10 to 60 seconds, depending on the etch rate.

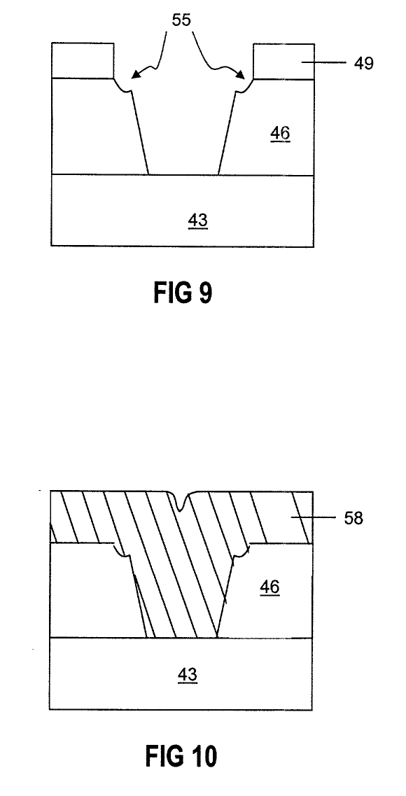

Turning to FIG. 9, a soft etching process is subsequently performed primarily to remove a portion of dielectric layer 46 on the top corner of the contact opening and, secondarily, to remove any residues on the bottom of the contact opening. In the illustrated embodiment, a part of the dielectric layer 46, beneath the portion of photoresist layer 49 removed in the photoresist descum process, is etched. The sidewall surface of the contact opening becomes substantially rounded at a top of the contact opening during the soft etching process, so that a diameter at the top of the contact opening is substantially greater than a diameter at the base of the opening. The soft etching process may be performed using, e.g., an isotropic plasma etch in which the conditions are controlled to achieve the desired results. The soft etching process may be performed in the same reaction chamber used for the previous etching processes. Moreover, the same reactants employed for the isotropic etching process may be employed for the soft etching process. Alternatively, the soft etching process may be performed using a wet etch chemistry commonly recognized as suitable to those skilled in the art.

The duration of the soft etching process is selected to terminate after a top corner 55 of the contact opening 52 has been at least partially removed to thereby increase a width of the contact opening 52, and preferably after the top corner 55 has been somewhat rounded, and more preferably after the top corner 55 has been formed into the substantially round profile depicted in FIG. 9 to attenuate and preferably eliminate the occurrence of voids. Thus, a contact opening having a rounded corner 55 is formed as a result of the soft etching process. The photoresist layer 49 is subsequently removed using known techniques, such as ashing.

FIG. 10 depicts the formation of a conductive material 58 in the contact opening. The contact opening may be filled with conductive layer 58 by sputtering from a metal target, such as a tungsten target. Alternatively, plating a metal, such as copper may form conductive layer 58 in the contact opening. As shown, conductive layer 58 is formed to a level above the upper surface of dielectric layer 46. Since the top corner of the contact opening is rounded, conductive layer 58 substantially fills the contact opening and is substantially free, and preferably completely free, of voids that could lower the conductivity of the resulting contact. In subsequent processing steps, conductive material 58 may be removed back to the surface of dielectric layer 46 to form a plug structure within the contact opening. Alternatively, conductive layer 58 may be maintained as embodied in FIG. 10, allowing conductive layer 58 to serve as both an interconnect residing on dielectric layer 46 and as an ohmic contact coupling the interconnect to substrate 43.

The above-described embodiments have been provided by way of example, and the present invention is not limited to these examples. Multiple variations and modification to the disclosed embodiments will occur, to the extent not mutually exclusive, to those skilled in the art upon consideration of the foregoing description. Such variations and modifications, however, fall well within the scope of the present invention as set forth in the following claims.

What is claimed is:

1. A method for forming a contact opening having a rounded corner, comprising:
forming a dielectric layer and a patterned photoresist layer on a substrate sequentially;
performing an isotropic etching process and a main etching process to form a contact opening in the dielectric layer;
performing a photoresist descum process to remove a portion of the photoresist layer; and
performing a soft etching process to round a corner at a top of the contact opening.

2. The method of claim 1, further comprising performing an over-etching process after the main etching process is performed.

3. The method of claim 1, wherein a pressure of the photoresist descum process is about 50-150 mTorr.

4. The method of claim 1, wherein a power of the photoresist descum process is about 50-200 W.

5. The method of claim 1, wherein a reactive gas of the photoresist descum process is O₂, and a flow rate of the reactive gas is about 5-80 sccm.

6. The method of claim 1, wherein a duration of the photoresist descum process is about 10-60 seconds.

7. The method of claim 1, wherein an etching rate of the photoresist layer in the photoresist descum process is about 2000-6000 angstroms/min.

8. The method of claim 1, wherein:
a pressure of the isotropic etching process is about 500-1000 mTorr; and
a power of the isotropic etching process is about 100-300 W.

9. The method of claim 1, wherein the isotropic etching process, the main etching process, the photoresist descum process and the soft etching process are all performed in-situ.

10. The method of claim 1, wherein reactive gases of the isotropic etching process are Ar/CF₄/CHF₃, and wherein a flow rate of Ar is about 50-150 sccm, the flow rate of CF₄ is about 10-30 sccm, and a flow rate of CHF₃ is about 10-30 sccm.

11. The method of claim 1, wherein the dielectric layer is selected from the group comprising BPSG, silicon oxide, silicon nitride, and silicon oxy-nitride.

12. A structure formed by the method of claim 1.

13. A method for forming at least one opening having a rounded corner, comprising:
forming a patterned layer on a material;
performing an etching process, using the patterned layer, to form at least one opening in the material;
removing at least one portion of the patterned layer adjacent to the at least one opening; and
performing a soft etching process on a part of the material beneath the at least one removed portion, to thereby round a corner of the material at a top of the at least one opening.

14. The method of claim 13, wherein:
the patterned layer is a patterned photoresist layer, the material is a dielectric layer, the at least one opening is at least one contact opening, and the etching process is a main etching progress;
the forming of a patterned layer on a material comprises forming a patterned photoresist layer on a dielectric layer, wherein the dielectric layer is disposed on a substrate; and
the removing of at least one portion of the patterned layer comprises performing a photoresist descum process to thereby remove at least one portion of the photoresist layer.

15. The method of claim 14, further comprising performing an over etching process after the main etching process is performed.

16. The method of claim 14, wherein a pressure of the photoresist descum process is about 50-50 mtorr.

17. The method of claim 14, wherein:
a power of the photoresist descum process is about 50-200 W; and
a duration of the photoresist descum process is about 10-60 seconds.

18. The method of claim 14, wherein:
a reactive gas of the photoresist descum process is O₂;
a flow rate of the reactive gas of the photoresist descum process is about 5-80 sccm; and
an etching rate of the photoresist layer in the photoresist descum process is about 2000-6000 angstroms/min.

19. The method of claim 14, wherein the isotropic etching process, the main etching process, the photoresist descum process and the soft etching process are all performed in-situ.

20. The method of claim 13, wherein the patterned layer is a patterned photoresist layer, the material is a dielectric layer, the at least one opening is a plurality of contact openings, and the etching process is a main etching process;
the forming of a patterned layer on a material comprises forming a patterned photoresist layer on a dielectric layer, wherein the dielectric layer is disposed on a substrate; and
the removing of at least one portion of the patterned layer comprises performing a photoresist descum process to thereby remove a plurality of portions of the photoresist layer.

21. The method of claim 14, wherein the dielectric layer comprises a BPSG layer.

22. A structure formed by the method of claim 14.

23. A semiconductor structure, comprising:
a dielectric layer disposed on a semiconductor substrate; and
at least one contact opening extending through the dielectric layer;
wherein the at least one contact opening comprises a sidewall surface that is substantially rounded at a top of the at least one contact opening, so that a diameter of the top of the at least one contact opening is greater than a diameter of a base of the at least one contact opening; and
wherein the at least one contact opening is filled with conductive layer.

24. The structure of claim 23, wherein:
the at least one contact opening comprises a plurality of contact openings; and
the dielectric layer is selected from the group comprising BPSG, silicon oxide, silicon nitride, and silicon oxy-nitride.
